(19) United States
(12) Patent Application Publication
(10) Pub. No.: US 2026/0209259 A1
(43) Pub. Date: Jul. 23, 2026

(54) HIGH PURITY PRECURSOR COMPOSITIONS AND RELATED METHODS

(71) Applicant: ENTEGRIS, INC., Billerica, MA (US)

(72) Inventor: David Kuiper, Brookfield, CT (US)

(21) Appl. No.: 19/456,600

(22) Filed: Jan. 22, 2026

Related U.S. Application Data
(60) Provisional application No. 63/748,026, filed on Jan. 22, 2025.

(51) Int. Cl. C07F 11/00; C23C 16/34

(52) U.S. Cl. CPC C07F 11/00; C23C 16/34

(57) ABSTRACT

High purity precursor compositions and related methods are provided herein. The method includes obtaining a first reactant and a second reactant. The method includes contacting the first reactant and the second reactant to form a reaction product. The reaction product has a purity of at least 90% as determined by a thermogravimetric analysis (TGA) residue at 400° C. The reaction product can be used as a deposition precursor.

### CROSS-REFERENCE TO RELATED APPLICATIONS

This application claims the benefit under 35 USC 119 of U.S. Provisional Patent Application No. 63/748,026, filed Jan. 22, 2025, the disclosure of which is hereby incorporated herein by reference in its entirety.

### FIELD

The present disclosure relates to high purity precursor compositions and related methods.

### BACKGROUND

Metal precursors are useful in the manufacturing of microelectronic devices.

### SUMMARY

Some embodiments relate to a composition. In some embodiments, the composition comprises a precursor compound. In some embodiments, the precursor compound comprises the formula:

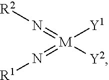

where:
M comprises at least one of molybdenum, tungsten, chromium, or any combination thereof;
R¹ and R² independently comprise at least one of an alkyl, an alkenyl, an alkynyl, or any combination thereof, and
Y¹ and Y² independently comprises at least one of a hydrocarbon functional group that does not contain a β-hydrogen, a silyl, an alkoxy, an amine, a thiol, or any combination thereof, or
Y¹ and Y² are bonded to form a cyclic ring.

In some embodiments, the precursor compound is present in an amount of 90% by weight or greater based on a total weight of the composition.

Some embodiments relate to a method. In some embodiments, the method comprises obtaining a precursor compound. In some embodiments, the precursor compound comprises the formula:

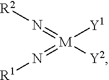

where:
M comprises at least one of molybdenum, tungsten, chromium, or any combination thereof;
R¹ and R² independently comprise at least one of an alkyl, an alkenyl, an alkynyl, or any combination thereof, and
Y¹ and Y² independently comprises at least one of a hydrocarbon functional group that does not contain a β-hydrogen, a silyl, an alkoxy, an amine, a thiol, or any combination thereof, or
Y¹ and Y² are bonded to form a cyclic ring.

In some embodiments, the method comprises heating the precursor compound to form a vaporized precursor. In some embodiment, the method comprises contacting a substrate with the vaporized precursor to obtain a film on the substrate.

Some embodiments relate to a method. In some embodiments, the method comprises obtaining a first reactant. In some embodiments, the first reactant comprises the formula:

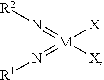

where:
M comprises at least one of molybdenum, tungsten, chromium, or any combination thereof;
R¹ and R² independently comprise at least one of an alkyl, an alkenyl, an alkynyl, or any combination thereof,
each X independently comprises a halide.

In some embodiments, the method comprises obtaining a second reactant. In some embodiments, the second reactant comprises the formula:

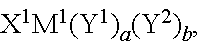

where:
X¹ comprises a halide;
M¹ comprises at least one of an alkali metal, an alkaline earth metal, or any combination thereof;
a is 0 or 1;
b is 0 or 1; and
Y¹ and Y² independently comprises at least one of a hydrocarbon functional group that does not contain a β-hydrogen, a silyl, an alkoxy, an amine, a thiol, or any combination thereof, or
Y¹ and Y² are bonded to form a cyclic ring.

In some embodiments, the method comprises contacting the first reactant and the second reactant to form a reaction product. In some embodiments, the reaction product comprises the formula:

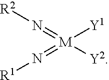

### BRIEF DESCRIPTION OF THE DRAWINGS

FIG. 1 is a flowchart of a method for forming a film 100, according to some embodiments.

FIG. 2 is a flowchart of a method for forming a reaction product 200, according to some embodiments.

FIG. 3 is a TGA of the crude reaction product of Example 1, according to some embodiments.

### DETAILED DESCRIPTION

As used herein, the term “contacting” refers to bringing two or more components into immediate or close proximity, or into direct contact.

As used herein, the term “alkyl” refers to a hydrocarbyl having from 1 to 30 carbon atoms. The alkyl may be attached via a single bond. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₃₀ alkyl, C₁-C₂₉ alkyl, C₁-C₂₈ alkyl, C₁-C₂₇ alkyl, C₁-C₂₇ alkyl, C₁-C₂₆ alkyl, C₁-C₂₅ alkyl, C₁-C₂₄ alkyl, C₁-C₂₃ alkyl, C₁-C₂₂ alkyl, C₁-C₂₁ alkyl, C₁-C₂₀ alkyl, C₁-C₁₉ alkyl, C₁-C₁₈ alkyl, C₁-C₁₇ alkyl, C₁-C₁₆ alkyl, C₁-C₁₅ alkyl, C₁-C₁₄ alkyl, C₁-C₁₃ alkyl, C₁-C₁₂ alkyl, C₁-C₁₁ alkyl, C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₁-C₂ alkyl, a C₂-C₃₀ alkyl, a C₃-C₃₀ alkyl, a C₄-C₃₀ alkyl, a C₅-C₃₀ alkyl, a C₆-C₃₀ alkyl, a C₇-C₃₀ alkyl, a C₈-C₃₀ alkyl, a C₉-C₃₀ alkyl, a C₁₀-C₃₀ alkyl, a C₁₁-C₃₀ alkyl, a C₁₂-C₃₀ alkyl, a C₁-C₃₀ alkyl, a C₁₄-C₃₀ alkyl, a C₁₅-C₃₀ alkyl, a C₁₆-C₃₀ alkyl, a C₁₇-C₃₀ alkyl, a C₁₈-C₃₀ alkyl, a C₁₉-C₃₀ alkyl, a C₂₀-C₃₀ alkyl, a C₂₁-C₃₀ alkyl, a C₂₂-C₃₀ alkyl, a C₂₃-C₃₀ alkyl, a C₂₄-C₃₀ alkyl, a C₂₅-C₃₀ alkyl, a C₂₆-C₃₀ alkyl, a C₂₇-C₃₀ alkyl, a C₂₈-C₃₀ alkyl, a C₂₉-C₃₀ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof. In some embodiments, the term “alkyl” refers generally to alkyls, alkenyls, and/or alkynyls.

As used herein, the term “alkenyl” refers to a hydrocarbyl having from 1 to 30 carbon atoms and at least one carbon-carbon double bond. In some embodiments, the alkenyl comprises or is selected from the group consisting of at least one of a C₁-C₃₀ alkenyl, C₁-C₂₉ alkenyl, C₁-C₂₈ alkenyl, C₁-C₂₇ alkenyl, C₁-C₂₇ alkenyl, C₁-C₂₆ alkenyl, C₁-C₂₅ alkenyl, C₁-C₂₄ alkenyl, C₁-C₂₃ alkenyl, C₁-C₂₂ alkenyl, C₁-C₂₁ alkenyl, C₁-C₂₀ alkenyl, C₁-C₁₉ alkenyl, C₁-C₁₈ alkenyl, C₁-C₁₇ alkenyl, C₁-C₁₆ alkenyl, C₁-C₁₅ alkenyl, C₁-C₁₄ alkenyl, C₁-C₁₃ alkenyl, C₁-C₁₂ alkenyl, C₁-C₁₁ alkenyl, C₁-C₁₀ alkenyl, a C₁-C₉ alkenyl, a C₁-C₈ alkenyl, a C₁-C₇ alkenyl, a C₁-C₆ alkenyl, a C₁-C₅ alkenyl, a C₁-C₄ alkenyl, a C₁-C₃ alkenyl, a C₁-C₂ alkenyl, a C₂-C₃₀ alkenyl, a C₃-C₃₀ alkenyl, a C₄-C₃₀ alkenyl, a C₅-C₃₀ alkenyl, a C₆-C₃₀ alkenyl, a C₇-C₃₀ alkenyl, a C₈-C₃₀ alkenyl, a C₉-C₃₀ alkenyl, a C₁₀-C₃₀ alkenyl, a C₁-C₃₀ alkenyl, a C₁₂-C₃₀ alkenyl, a C₁₃-C₃₀ alkenyl, a C₁₄-C₃₀ alkenyl, a C₁₅-C₃₀ alkenyl, a C₁₆-C₃₀ alkenyl, a C₁₇-C₃₀ alkenyl, a C₁₈-C₃₀ alkenyl, a C₁₉-C₃₀ alkenyl, a C₂₀-C₃₀ alkenyl, a C₂₁-C₃₀ alkenyl, a C₂₂-C₃₀ alkenyl, a C₂₃-C₃₀ alkenyl, a C₂₄-C₃₀ alkenyl, a C₂₅-C₃₀ alkenyl, a C₂₆-C₃₀ alkenyl, a C₂₇-C₃₀ alkenyl, a C₂₈-C₃₀ alkenyl, a C₂₉-C₃₀ alkenyl, a C₂-C₁₀ alkenyl, a C₃-C₁₀ alkenyl, a C₄-C₁₀ alkenyl, a C₅-C₁₀ alkenyl, a C₆-C₁₀ alkenyl, a C₇-C₁₀ alkenyl, a C₅-C₁₀ alkenyl, a C₂-C₉ alkenyl, a C₂-C₅ alkenyl, a C₂-C₇ alkenyl, a C₂-C₆ alkenyl, a C₂-C₅ alkenyl, a C₃-C₅ alkenyl, or any combination thereof. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof.

As used herein, the term “alkynyl” refers to a hydrocarbyl having from 1 to 30 carbon atoms and at least one carbon-carbon triple bond. In some embodiments, the alkynyl comprises or is selected from the group consisting of at least one of a C₁-C₃₀ alkynyl, C₁-C₂₉ alkynyl, C₁-C₂₈ alkynyl, C₁-C₂₇ alkynyl, C₁-C₂₇ alkynyl, C₁-C₂₆ alkynyl, C₁-C₂₅ alkynyl, C₁-C₂₄ alkynyl, C₁-C₂₃ alkynyl, C₁-C₂₂ alkynyl, C₁-C₂₁ alkynyl, C₁-C₂₀ alkynyl, C₁-C₁₉ alkynyl, C₁-C₁₈ alkynyl, C₁-C₁₇ alkynyl, C₁-C₁₆ alkynyl, C₁-C₁₅ alkynyl, C₁-C₁₄ alkynyl, C₁-C₁₃ alkynyl, C₁-C₁₂ alkynyl, C₁-C₁₁ alkynyl, C₁-C₁₀ alkynyl, a C₁-C₉ alkynyl, a C₁-C₈ alkynyl, a C₁-C₇ alkynyl, a C₁-C₆ alkynyl, a C₁-C₅ alkynyl, a C₁-C₄ alkynyl, a C₁-C₃ alkynyl, a C₁-C₂ alkynyl, a C₂-C₃₀ alkynyl, a C₃-C₃₀ alkynyl, a C₄-C₃₀ alkynyl, a C₅-C₃₀ alkynyl, a C₆-C₃₀ alkynyl, a C₇-C₃₀ alkynyl, a C₈-C₃₀ alkynyl, a C₉-C₃₀ alkynyl, a C₁₀-C₃₀ alkynyl, a Cₙ-C₃₀ alkynyl, a C₁₂-C₃₀ alkynyl, a C₁₃-C₃₀ alkynyl, a C₁₄-C₃₀ alkynyl, a C₁₅-C₃₀ alkynyl, a C₁₆-C₃₀ alkynyl, a C₁₇-C₃₀ alkynyl, a Cis-C₃₀ alkynyl, a C₁₉-C₃₀ alkynyl, a C₂₀-C₃₀ alkynyl, a C₂₁-C₃₀ alkynyl, a C₂₂-C₃₀ alkynyl, a C₂₃-C₃₀ alkynyl, a C₂₄-C₃₀ alkynyl, a C₂₅-C₃₀ alkynyl, a C₂₆-C₃₀ alkynyl, a C₂₇-C₃₀ alkynyl, a C₂₈-C₃₀ alkynyl, a C₂₉-C₃₀ alkynyl, a C₂-C₁₀ alkynyl, a C₃-C₁₀ alkynyl, a C₄-C₁₀ alkynyl, a C₅-C₁₀ alkynyl, a C₆-C₁₀ alkynyl, a C₇-C₁₀ alkynyl, a C₅-C₁₀ alkynyl, a C₂-C₉ alkynyl, a C₂-C₈ alkynyl, a C₂-C₇ alkynyl, a C₂-C₆ alkynyl, a C₂-C₅ alkynyl, a C₃-C₅ alkynyl, or any combination thereof. Examples of alkynyl groups include, without limitation, at least one of ethynyl, propynyl, n-butynyl, n-pentynyl, 3-methyl-1-butynyl, n-hexynyl, methyl-pentynyl, or any combination thereof.

As used herein, the term “amino” and/or “amine” refers to a functional group of formula —N(R^{a}R^{b}), wherein R^{a} and R^{b} are independently a hydrogen, an alkyl (as defined herein), or a silyl (as defined herein), or R^{a} and R^{b} are bonded to each other to form a C₃-C₂₀ N-heterocycle. In some embodiments, the amino may comprise an alkylamino or a dialkylamino. In some embodiments, the amino may comprise at least one of methylamino, dimethylamino, ethylamino, diethylamino, isopropylamino, di-isopropylamino, butylamino, sec-butylamino, tert-butylamino, di-sec-butylamino, isobutylamino, di-isobutylamino, di-tert-pentylamino, ethylmethylamino, isopropyl-n-propylamino, or any combination thereof. Examples of the alkylamines may include, without limitation, one or more of the following: primary alkylamines, such as, for example and without limitation, methylamine, ethylamine, n-propylamine, isopropylamine, n-butylamine, sec-butylamine, isobutylamine, t-butylamine, pentylamine, 2-aminopentane, 3-aminopentane, 1-amino-2-methylbutane, 2-amino-2-methylbutane, 3-amino-2-methylbutane, 4-amino-2-methylbutane, hexylamine, 5-amino-2-methylpentane, heptylamine, octylamine, nonylamine, decylamine, undecylamine, dodecylamine, tridecylamine, tetradecylamine, pentadecylamine, hexadecylamine, heptadecylamine, and octadecylamine; secondary alkylamines, such as, for example and without limitation, dimethylamine, diethylamine, dipropylamine, diisopropylamine, dibutylamine, diisobutylamine, di-sec-butylamine, di-t-butylamine, dipentylamine, dihexylamine, diheptylamine, dioctylamine, dinonylamine, didecylamine, methylethylamine, methylpropylamine, methylisopropylamine, methylbutylamine, methylisobutylamine, methyl-sec-butylamine, methyl-t-butylamine, methylamylamine, methylisoamylamine, ethylpropylamine, ethylisopropylamine, ethylbutylamine, ethylisobutylamine, ethyl-sec-butylamine, ethylamine, ethylisoamylamine, propylbutylamine, and propylisobutylamine; and tertiary alkylamines, such as, for example and without limitation, trimethylamine, triethylamine, tripropylamine, tributylamine, tripentylamine, dimethylethylamine, methyldiethylamine, and methyldipropylamine. Examples of polyamines may include, without limitation, one or more of the following: ethylenediamine, propylenediamine, trimethylenediamine, tetramethylenediamine, 1,3-diaminobutane, 2,3-diaminobutane, pentamethylenediamine, 2,4-diaminopentane, hexamethylenediamine, heptamethylenediamine, octamethylenediamine, nonamethylenediamine, N-methylethylenediamine, N,N-dimethylethylenediamine, trimethylethylenediamine, N-ethylethylenediamine, N,N-diethylethylenediamine, triethylethylenediamine, 1,2,3-triaminopropane, hydrazine, tris(2-aminoethyl)amine, tetra(aminomethyl)methane, diethylenetriamine, triethylenetetramine, tetraethylpentamine, heptaethyleneoctamine, nonaethylenedecamine, and diazabicyloundecene. Unless otherwise provided herein, the terms “amine” and “amino” may be used interchangeably throughout this disclosure.

As used herein, the term “alkoxy” or “alkoxide” refers to a functional group of formula —OR^{c}, wherein R^{c} is an alkyl (as defined herein) or a silylalkyl. In some embodiments, the alkoxy may comprise, consist of, or consist essentially of, or may selected from the group consisting of, at least one of methoxy, ethoxy, methoxy, ethoxy, n-propoxy, 1-methylethoxy (isopropoxy), n-butoxy, iso-butoxy, sec-butoxy, tert-butoxy, or any combination thereof.

As used herein, the term “silyl” refers to a functional group of formula —Si(R^{e}R^{f}R^{g}), where each of R^{e}, R^{f}, and R^{g} is independently a hydrogen or an alkyl, as defined herein. In some embodiments, the silyl is a functional group of formula —SiH₃. In some embodiments, the silyl is a functional group of formula —SiR^{e}H₂, where R^{e} is not hydrogen. In some embodiments, the silyl is a functional group of formula —SiR^{e}R^{f}H, where R^{e} and R^{f} are not hydrogen. In some embodiments, the silyl is a functional group of the formula —Si(R^{e}R^{f}R^{g}), where R^{e}, R^{f}, and R^{g} are not hydrogen. In some embodiments, the silyl is a functional group of formula —Si(CH₃)₃.

As used herein, the term “silylalkyl” refers to an alkyl as defined herein, wherein at least one of the hydrogen atoms of the alkyl is replaced with a silyl as defined herein. In some embodiments, the term “silylalkyl” refers to a functional group of formula -(alkyl)Si(R^{e}R^{f}R^{g}), wherein the alkyl is defined above and wherein R^{e}, R^{f}, and R^{g} are defined above. In some embodiments, the silylalky is a functional group of formula —(CH₂)ₘSi(R^{e}R^{f}R^{g}), where m is 1 to 10 and where R^{e}, R^{f} and R^{g} are defined above. In some embodiments, the silylalkyl is a functional group of formula —CH₂Si(CH₃)₃.

As used herein, the term “thiol” refers to a functional group of formula —SR, where R is independently a hydrogen or an alkyl, as defined herein. In some embodiments, the thiol is a functional group of formula —SH. In some embodiments, the thiol is a functional group of formula —S(CH₃).

As used herein, the term “halide” refers to a —Cl, —Br, —I, or —F.

As used herein, the term “metal” refers to at least one of an alkali metal, an alkaline earth metal, a transition metal, a post-transition metal, or any combination thereof. In some embodiments, the metal comprises a metal cation. In some embodiments, the metal cation comprises at least one of a lithium cation, a sodium cation, a potassium cation, a rubidium cation, a cesium cation, a francium cation, a beryllium cation, a magnesium cation, a calcium cation, a strontium cation, a barium cation, a radium cation, a scandium cation, a titanium cation, a vanadium cation, a chromium cation, a manganese cation, an iron cation, a cobalt cation, a nickel cation, a copper cation, a zinc cation, a yttrium cation, a zirconium cation, a niobium cation, a molybdenum cation, a technetium cation, a ruthenium cation, a rhodium cation, a palladium cation, a silver cation, a cadmium cation, a hafnium cation, a tantalum cation, a tungsten cation, a rhenium cation, an osmium cation, an iridium cation, a platinum cation, a gold cation, a mercury cation, an aluminum cation, a gallium cation, an indium cation, tin cation, a thallum cation, a lead cation, a bismuth cation, a polonium cation, or any combination thereof. The charge(s) of the metal cations are known and, for simplicity, thus are not repeated here; however, it will be appreciated that the metal cations can have any known charge.

Some embodiments relate to precursors and related methods. At least some of these embodiments relate to precursors useful in the fabrication of microelectronic devices, including semiconductor devices, and the like. For example, the precursors can be used to form metal-containing films by one or more deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

Some embodiments relate to a composition. In some embodiments, the composition comprises a precursor compound of the formula:

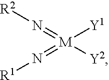

where:
M comprises at least one of molybdenum, tungsten, chromium, or any combination thereof;
R¹ and R² independently comprise at least one of an alkyl, an alkenyl, an alkynyl, or any combination thereof, and
Y¹ and Y² independently comprises at least one of a hydrocarbon functional group that does not contain a β-hydrogen, a silyl, an alkoxy, an amine, a thiol, or any combination thereof, or
Y¹ and Y² are bonded to form a cyclic ring.

In some embodiments, M comprises a molybdenum. In some embodiments, M comprises a tungsten. In some embodiments, M comprises a chromium.

In some embodiments, R¹ comprises at least one of an alkyl, an alkenyl, an alkynyl, or any combination thereof. In some embodiments, R² comprises at least one of an alkyl, an alkenyl, an alkynyl, or any combination thereof. In some embodiments, R¹ and R² are the same. In some embodiments, R¹ and R² are different.

In some embodiments, Y¹ and Y² independently comprises at least one of a hydrocarbon functional group that does not contain a β-hydrogen, a silyl, an alkoxy, an amine, a thiol, or any combination thereof. In some embodiments, Y¹ and Y² are the same. In some embodiments, Y¹ and Y² are different. In some embodiments, Y¹ and Y² are bonded to form a cyclic ring.

In some embodiments, Y¹ and Y² independently comprise at least one of:

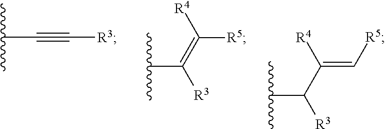

or
any combination thereof.

In some embodiments, R³, R⁴, and R⁵ independently comprise at least one of an alkyl, an alkenyl, an alkynyl, or any combination thereof. In some embodiments, R³, R⁴, and R⁵ do not comprise a hydrogen. In some embodiments, R³ comprises at least one of a hydrogen, an alkyl, an alkenyl, an alkynyl, or any combination thereof. In some embodiments, R³ does not comprises a hydrogen. In some embodiments, R⁴ comprises at least one of an alkyl, an alkenyl, an alkynyl, or any combination thereof. In some embodiments, R⁴ does not comprises a hydrogen. In some embodiments, R⁵ comprises at least one of an alkyl, an alkenyl, an alkynyl, or any combination thereof. In some embodiments, R⁴ does not comprises a hydrogen. In some embodiments, R³, R⁴, and R⁵ are all the same. In some embodiments, R³, R⁴, and R⁵ are all different. In some embodiments, at least one of R³, R⁴, and R⁵ is different. In some embodiments, at least two of R³, R⁴, and R⁵ are different. In some embodiments, at least two of R³, R⁴, and R⁵ are the same.

In some embodiments, when Y¹ and Y² are bonded to form a cyclic ring, the cyclic ring has the formula:

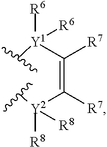

where:
Y¹ and Y² independently comprises at least one of an oxygen, a nitrogen, a sulfur, or any combination thereof; and
each R⁶, R⁷, and R⁸ independently comprise at least one of an alkyl, an alkenyl, an alkynyl, or any combination thereof.

In some embodiments, Y¹ comprises at least one of an oxygen, a nitrogen, a sulfur, or any combination thereof. In some embodiments, Y² comprises at least one of an oxygen, a nitrogen, a sulfur, or any combination thereof. In some embodiments, Y¹ and Y² are the same. In some embodiments, Y¹ and Y² are different.

In some embodiments, each R⁶ comprises at least one of an alkyl, an alkenyl, an alkynyl, or any combination thereof. In some embodiments, each R⁶ is the same. In some embodiments, each R⁶ is different. In some embodiments, each R⁷ comprises at least one of an alkyl, an alkenyl, an alkynyl, or any combination thereof. In some embodiments, each R⁷ is the same. In some embodiments, each R⁷ is different. In some embodiments, each R⁸ comprises at least one of an alkyl, an alkenyl, an alkynyl, or any combination thereof. In some embodiments, each R⁸ is the same. In some embodiments, each R⁸ is different. In some embodiments, R⁶, R⁷, and R⁸ are the same. In some embodiments, R⁶, R⁷, and R⁸ are different. In some embodiments, at least one of R⁶, R⁷, and R⁸ is different. In some embodiments, at least two of R⁶, R⁷, and R⁸ are different. In some embodiments, at least two of R⁶, R⁷, and R⁸ are the same.

In some embodiments, the precursor compound comprises the formula:

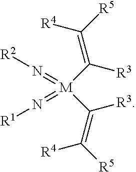

In some embodiments, the precursor compound is present in an amount of at least 90% by weight based on the total weight of the composition. In some embodiments, the precursor compound is present in an amount of at least 91%, at least 92%, at least 93%, at least 94%, at least 95%, at least 96%, at least 97%, at least 98%, at least 99%, at least 99.1%, at least 99.2%, at least 99.3%, at least 99.4%, at least 99.5%, at least 99.6%, at least 99.7%, at least 99.8%, at least 99.9%, at least 99.91%, at least 99.92%, at least 99.93%, at least 99.94%, at least 99.95%, at least 99.96%, at least 99.97%, at least 99.98%, or at least 99.99% based on the total weight of the composition.

In some embodiments, the precursor compound is present in an amount of 90% to 99.99%, or any range or subrange between 90% to 99.99%, by weight based on the total weight of the composition. In some embodiments, the precursor compound is present in an amount of 90% to 99.98%, 90% to 99.97%, 90% to 99.96%, 90% to 99.95%, 90% to 99.94%, 90% to 99.93%, 90% to 99.92%, 90% to 99.91%, 90% to 99.9%, 90% to 99.8%, 90% to 99.7%, 90% to 99.6%, 90% to 99.5%, 90% to 99.4%, 90% to 99.3%, 90% to 99.2%, 90% to 99.1%, 90% to 99%, 90% to 98%, 90% to 97%, 90% to 96%, 90% to 95%, 90% to 94%, 90% to 93%, 90% to 92%, 90% to 91%, 91% to 99.99%, 92% to 99.99%, 93% to 99.99%, 94% to 99.99%, 95% to 99.99%, 96% to 99.99%, 97% to 99.99%, 98% to 99.99%, 99% to 99.99%, 99.1% to 99.99%, 99.2% to 99.99%, 99.3% to 99.99%, 99.4% to 99.99%, 99.5% to 99.99%, 99.6% to 99.99%, 99.7% to 99.99%, 99.8% to 99.99%, 99.9% to 99.99%, 99.91% to 99.99%, 99.92% to 99.99%, 99.93% to 99.99%, 99.94% to 99.99%, 99.95% to 99.99%, 99.96% to 99.99%, 99.97% to 99.99%, or 99.98% to 99.99%.

In some embodiments, the precursor compound has a purity of at least 90% as determined TGA residue at 400° C. For example, in some embodiments, the precursor compound has a purity of, at least 91%, at least 92%, at least 93%, at least 94%, at least 95%, at least 96%, at least 97%, at least 98%, at least 99%, at least 99.5%, at least 99.9%, at least 99.95%, or at least 99.99% as determined by a TGA residue at 400° C.

In some embodiments, the precursor compound has a purity of 90% to 99.99%, or any range or subrange between 90% to 99.99%, as determined by a TGA residue at 400° C. In some embodiments, the precursor compound has a purity of 90% to 99.95%, 90% to 99.9%, 90% to 99.5%, 90% to 99%, 90% to 98%, 90% to 97%, 90% to 96%, 90% to 95%, 90% to 94%, 90% to 93%, 90% to 92%, 90% to 91%, 91% to 99.99%, 92% to 99.99%, 93% to 99.99%, 94% to 99.99%, 95% to 99.99%, 96% to 99.99%, 97% to 99.99%, 98% to 99.99%, 99% to 99.99%, 99.5% to 99.99%, 99.9% to 99.99% or 99.95 to 99.99%, as determined by a TGA residue at 400° C.

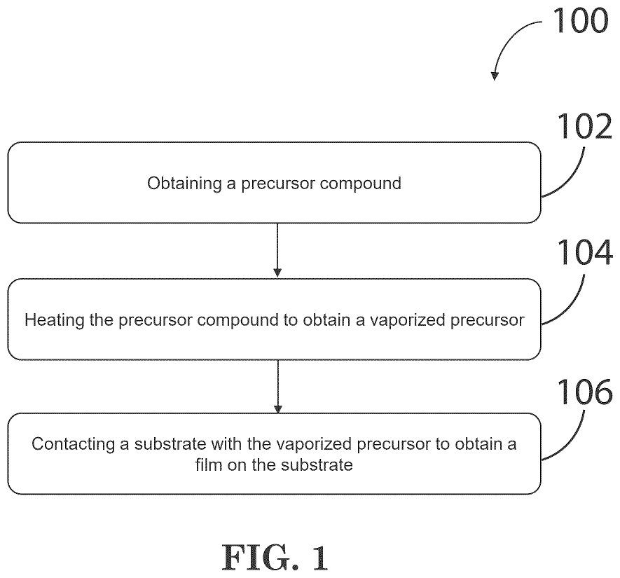

FIG. 1 is a flowchart of a method for making a film 100, according to some embodiments. As shown in FIG. 1, the method for making a film 100 may comprise one or more of the following steps: obtaining 102 a precursor compound, heating 104 the precursor compound to obtain a vaporized precursor, contacting 106 a substrate with the vaporized precursor to form a film on the substrate.

At step 102, in some embodiments, the method comprises obtaining a precursor compound. The precursor compound may comprise any one or more of the precursor compounds disclosed herein. In some embodiments, the obtaining comprises obtaining a vessel comprising the precursor compound. In some embodiments, the obtaining comprises obtaining a container comprising the precursor compound. In some embodiments, the precursor compound may be obtained in a container or other vessel in which the precursor compound is to be heated.

In some embodiments, the precursor compound comprises the formula:

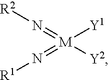

where:
M comprises at least one of molybdenum, tungsten, chromium, or any combination thereof;
R¹ and R² independently comprise at least one of an alkyl, an alkenyl, an alkynyl, or any combination thereof, and
Y¹ and Y² independently comprises at least one of a hydrocarbon functional group that does not contain a β-hydrogen, a silyl, an alkoxy, an amine, a thiol, or any combination thereof, or
Y¹ and Y² are bonded to form a cyclic ring.

In some embodiments, M comprises a molybdenum. In some embodiments, M comprises a tungsten. In some embodiments, M comprises a chromium.

In some embodiments, R¹ comprises at least one of an alkyl, an alkenyl, an alkynyl, or any combination thereof. In some embodiments, R² comprises at least one of an alkyl, an alkenyl, an alkynyl, or any combination thereof. In some embodiments, R¹ and R² are the same. In some embodiments, R¹ and R² are different.

In some embodiments, Y¹ and Y² independently comprises at least one of a hydrocarbon functional group that does not contain a β-hydrogen, a silyl, an alkoxy, an amine, a thiol, or any combination thereof. In some embodiments, Y¹ and Y² are the same. In some embodiments, Y¹ and Y² are different. In some embodiments, Y¹ and Y² are bonded to form a cyclic ring.

In some embodiments, Y¹ and Y² independently comprise at least one of:

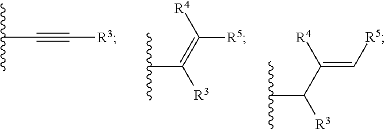

or
any combination thereof.

In some embodiments, R³, R⁴, and R⁵ independently comprise at least one of an alkyl, an alkenyl, an alkynyl, or any combination thereof. In some embodiments, R³ comprises at least one of an alkyl, an alkenyl, an alkynyl, or any combination thereof. In some embodiments, R⁴ comprises at least one of an alkyl, an alkenyl, an alkynyl, or any combination thereof. In some embodiments, R⁵ comprises at least one of an alkyl, an alkenyl, an alkynyl, or any combination thereof. In some embodiments, R³, R⁴, and R⁵ are all the same. In some embodiments, R³, R⁴, and R⁵ are all different. In some embodiments, at least one of R³, R⁴, and R⁵ is different. In some embodiments, at least two of R³, R⁴, and R⁵ are different. In some embodiments, at least two of R³, R⁴, and R⁵ are the same.

In some embodiments, when Y¹ and Y² are bonded to form a cyclic ring, the cyclic ring has the formula:

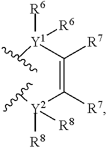

where:
Y¹ and Y² independently comprises at least one of an oxygen, a nitrogen, a sulfur, or any combination thereof, and
each R⁶, R⁷, and R⁸ independently comprise at least one of an alkyl, an alkenyl, an alkynyl, or any combination thereof.

In some embodiments, Y¹ comprises at least one of an oxygen, a nitrogen, a sulfur, or any combination thereof. In some embodiments, Y² comprises at least one of an oxygen, a nitrogen, a sulfur, or any combination thereof. In some embodiments, Y¹ and Y² are the same. In some embodiments, Y¹ and Y² are different.

In some embodiments, each R⁶ comprises at least one of an alkyl, an alkenyl, an alkynyl, or any combination thereof. In some embodiments, each R⁶ is the same. In some embodiments, each R⁶ is different. In some embodiments, each R⁷ comprises at least one of an alkyl, an alkenyl, an alkynyl, or any combination thereof. In some embodiments, each R⁷ is the same. In some embodiments, each R⁷ is different. In some embodiments, each R⁸ comprises at least one of an alkyl, an alkenyl, an alkynyl, or any combination thereof. In some embodiments, each R⁸ is the same. In some embodiments, each R⁸ is different. In some embodiments, R⁶, R⁷, and R⁸ are the same. In some embodiments, R⁶, R⁷, and R⁸ are different. In some embodiments, at least one of R⁶, R⁷, and R⁸ is different. In some embodiments, at least two of R⁶, R⁷, and R⁸ are different. In some embodiments, at least two of R⁶, R⁷, and R⁸ are the same.

In some embodiments, the precursor compound comprises the formula:

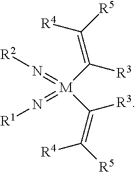

At step 104, in some embodiments, the method comprises heating the precursor compound to obtain a vaporized precursor. The heating may comprise heating the precursor compound sufficient to obtain the vaporized precursor. In some embodiments, the heating may comprise vaporizing the precursor compound to obtain the vaporized precursor. In some embodiments, the vaporizing comprises heating a container comprising the precursor. In some embodiments, the heating comprises heating the precursor in a deposition chamber in which a vapor deposition process is performed. In some embodiments, the heating comprises heating a conduit for delivering the precursor compound, the vaporized precursor, or any combination thereof to, for example, a deposition chamber. In some embodiments, the heating comprises operating a vapor delivery system comprising the precursor. In some embodiments, the heating comprises heating to a temperature sufficient to vaporize the precursor compound to obtain the vaporized precursor. In some embodiments, the heating comprises heating to a temperature below a decomposition temperature of at least one of the precursor compound, the vaporized precursor, or any combination thereof. In some embodiments, the precursor compound may be present in a gas phase or other vaporizable phase, in which case the step 104 is optional and not required. For example, in some embodiments, the precursor compound comprises the vaporized precursor.

At step 106, in some embodiments, the method comprises contacting a substrate with the vaporized precursor to obtain a film on the substrate. In some embodiments, the contacting comprises exposing, under vapor deposition conditions, a substrate to the vaporized precursor to form a film on the substrate. The contacting or exposing may be performed in any system, apparatus, device, assembly, chamber thereof, or component thereof suitable for vapor deposition processes, including, for example and without limitation, a deposition chamber, among others.

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The vapor deposition conditions may comprise a deposition temperature. The deposition temperature may be a temperature less than the thermal decomposition temperature of the vaporized precursor. The deposition temperature may be sufficiently high to reduce or avoid condensation of the vaporized precursor. In some embodiments, the substrate may be heated to the deposition temperature. In some embodiments, the chamber or other vessel in which the substrate is contacted with the vaporized precursor is heated to the deposition temperature. In some embodiments, the vaporized precursor may be heated to the deposition temperature.

The deposition temperature may be a temperature of 200° C. to 2500° C., or any range or subrange between 200° C. and 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2500° C., such as, for example and without limitation, a temperature of 400° C. to 2000, 500° C. to 2000° C., 550° C. to 2400° C., 600° C. to 2400° C., 625° C. to 2400° C., 650° C. to 2400° C., 675° C. to 2400° C., 700° C. to 2400° C., 725° C. to 2400° C., 750° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° C. to 2400° C., 1200° C. to 2400° C., 1300° C. to 2400° C., 1400° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° C. to 2400° C., 2300° C. to 2400° C., 500° C. to 2000° C., 500° C. to 1900° C., 500° C. to 1800° C., 500° C. to 1700° C., 500° C. to 1600° C., 500° C. to 1500° C., 500° C. to 1400° C., 500° C. to 1300° C., 500° C. to 1200° C., 500° C. to 1100° C., 500° C. to 1000° C., 500° C. to 1000° C., 500° C. to 900° C., or 500° C. to 800° C.

The vapor deposition conditions may comprise a deposition pressure. In some embodiments, the deposition pressure may comprise a vapor pressure of the vaporized precursor. In some embodiments, the deposition pressure may comprise a chamber pressure.

The deposition pressure may be a pressure of 0.001 Torr to 100 Torr, or any range or subrange between 0.001 Torr and 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 100 mTorr to 300 mTorr, 150 mTorr to 300 mTorr, 200 mTorr to 300 mTorr, or 150 mTorr to 250 mTorr, or 150 mTorr to 225 mTorr.

The substrate may comprise at least one of Si, Co, Cu, Al, W, WN, WC, TiN, Mo, MoC, SiO₂, W, SiN, WCN, Al₂O₃, AlN, ZrO₂, La₂O₃, TaN, RuO₂, IrO₂, Nb₂O₃, Y₂O₃, hafnium oxide, or any combination thereof.

In some embodiments, the film comprises less than 0.1% by weight of a halide based on a total weight of the film. In some embodiments, the film comprises less than 0.05%, less than 0.01%, less than 0.005%, less than 0.001%, less than 0.0005%, or less than 0.0001% by weight of a halide based on a total weight of the film. In some embodiments, the film comprises 0.0001% to 0.1%, or any range or subrange between 0.0001% to 0.1%, by weight of a halide based on a total weight of the film. In some embodiments, the film comprises 0.0001% to 0.05%, 0.0001% to 0.01%, 0.0001% to 0.005%, 0.0001% to 0.001%, 0.0001% to 0.0005%, 0.0005% to 0.1%, 0.001% to 0.1%, 0.005% to 0.1%, 0.01% to 0.1%, or 0.05% to 0.1% by weight of a halide based on a total weight of the film. In some embodiments, the film does not comprise a halide.

In some embodiments, the film comprises at least one of a molybdenum nitride, a chromium nitride, a tungsten nitride, or any combination thereof. In some embodiments, the film comprises a molybdenum nitride. In some embodiments, the film comprises a chromium nitride. In some embodiments, the film comprises a tungsten nitride.

Some embodiments relate to a film on a substrate. In some embodiments, the film comprises any film formed according to the methods disclosed herein. In some embodiments, the film comprises any film prepared from any one or more of the precursors disclosed herein.

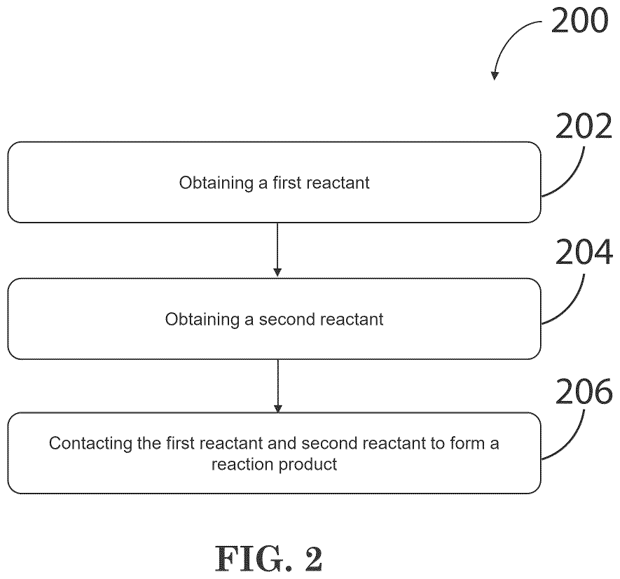

FIG. 2 is a flowchart of a method for making a precursor compound 200, according to some embodiments. As shown in FIG. 2, the method for making a precursor compound 200 may comprise one or more of the following steps: obtaining 202 a first reactant, obtaining 204 a second reactant, and contacting 206 the first reactant and the second reactant to form a reaction product.

At step 202, in some embodiments, the method comprises obtaining a first reactant. In some embodiments, the obtaining comprises obtaining a vessel comprising the first reactant. In some embodiments, the obtaining comprises obtaining a container comprising the first reactant. In some embodiments, the first reactant may be obtained in a container or other vessel in which the first reactant is to be reacted.

In some embodiments, the first reactant comprises the formula:

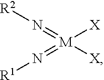

where:
M comprises at least one of molybdenum, tungsten, chromium, or any combination thereof;
R¹ and R² independently comprise at least one of an alkyl, an alkenyl, an alkynyl, or any combination thereof,
each X independently comprises a halide.

In some embodiments, M comprises a molybdenum. In some embodiments, M comprises a tungsten. In some embodiments, M comprises a chromium.

In some embodiments, R¹ comprises at least one of an alkyl, an alkenyl, an alkynyl, or any combination thereof. In some embodiments, R² comprises at least one of an alkyl, an alkenyl, an alkynyl, or any combination thereof. In some embodiments, R¹ and R² are the same. In some embodiments, R¹ and R² are different.

In some embodiments, each X comprises the same halide. In some embodiments, each X comprises a different halide.

At step 204, in some embodiments, the method comprises obtaining a second reactant. In some embodiments, the obtaining comprises obtaining a vessel comprising the second reactant. In some embodiments, the obtaining comprises obtaining a container comprising the second reactant. In some embodiments, the second reactant may be obtained in a container or other vessel in which the second reactant is to be reacted.

In some embodiments, the second reactant comprises the formula:

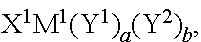

where:
X¹ comprises a halide;
M¹ comprises at least one of an alkali metal, an alkaline earth metal, a zinc, or any combination thereof,
a is 0 or 1;
b is 0 or 1; and
Y¹ and Y² independently comprises at least one of a hydrocarbon functional group that does not contain a β-hydrogen, a silyl, an alkoxy, an amine, a thiol, or any combination thereof, or
Y¹ and Y² are bonded to form a cyclic ring.

In some embodiments, X¹ comprises the same halide as each X of the first reactant. In some embodiments, X¹ comprises the same halide as at least one X of the first reactant. In some embodiments, X¹ comprises a different halide than each X of the first reactant. In some embodiments, X¹ comprises a different halide than at least one X of the first reactant.

In some embodiments, M¹ comprises an alkali metal. In some embodiments, M¹ comprises an alkaline earth metal. In some embodiments, M¹ comprises a zinc. In some embodiments, M¹ comprises at least one of a lithium, a sodium a potassium, a rubidium, a cesium, a francium, a beryllium, a magnesium, a calcium, a strontium, a barium, a radium, a zinc, or any combination thereof.

In some embodiments, a is 0. In some embodiments, a is 1. In some embodiments, b is 0. In some embodiments, b is 1. In some embodiments, a and b are the same. In some embodiments, a and b are different.

In some embodiments, Y¹ and Y² independently comprises at least one of a hydrocarbon functional group that does not contain a β-hydrogen, a silyl, an alkoxy, an amine, a thiol, or any combination thereof. In some embodiments, Y¹ and Y² are the same. In some embodiments, Y¹ and Y² are different. In some embodiments, Y¹ and Y² are bonded to form a cyclic ring.

In some embodiments, Y¹ and Y² independently comprise at least one of:

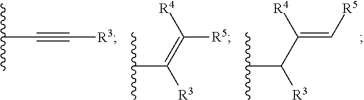

or
any combination thereof.

In some embodiments, R³, R⁴, and R⁵ independently comprise at least one of an alkyl, an alkenyl, an alkynyl, or any combination thereof. In some embodiments, R³ comprises at least one of an alkyl, an alkenyl, an alkynyl, or any combination thereof. In some embodiments, R⁴ comprises at least one of an alkyl, an alkenyl, an alkynyl, or any combination thereof. In some embodiments, R⁵ comprises at least one of an alkyl, an alkenyl, an alkynyl, or any combination thereof. In some embodiments, R³, R⁴, and R⁵ are all the same. In some embodiments, R³, R⁴, and R⁵ are all different. In some embodiments, at least one of R³, R⁴, and R⁵ is different. In some embodiments, at least two of R³, R⁴, and R⁵ are different. In some embodiments, at least two of R³, R⁴, and R⁵ are the same.

In some embodiments, when Y¹ and Y² are bonded to form a cyclic ring, the cyclic ring has the formula:

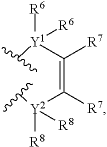

where:
Y¹ and Y² independently comprises at least one of an oxygen, a nitrogen, a sulfur, or any combination thereof; and
each R⁶, R⁷, and R⁸ independently comprise at least one of an alkyl, an alkenyl, an alkynyl, or any combination thereof.

In some embodiments, Y¹ comprises at least one of an oxygen, a nitrogen, a sulfur, or any combination thereof. In some embodiments, Y² comprises at least one of an oxygen, a nitrogen, a sulfur, or any combination thereof. In some embodiments, Y¹ and Y² are the same. In some embodiments, Y¹ and Y² are different.

In some embodiments, each R⁶ comprises at least one of an alkyl, an alkenyl, an alkynyl, or any combination thereof. In some embodiments, each R⁶ is the same. In some embodiments, each R⁶ is different. In some embodiments, each R⁷ comprises at least one of an alkyl, an alkenyl, an alkynyl, or any combination thereof. In some embodiments, each R⁷ is the same. In some embodiments, each R⁷ is different. In some embodiments, each R⁸ comprises at least one of an alkyl, an alkenyl, an alkynyl, or any combination thereof. In some embodiments, each R⁸ is the same. In some embodiments, each R⁸ is different. In some embodiments, R⁶, R⁷, and R⁸ are the same. In some embodiments, R⁶, R⁷, and R⁸ are different. In some embodiments, at least one of R⁶, R⁷, and R⁸ is different. In some embodiments, at least two of R⁶, R⁷, and R⁸ are different. In some embodiments, at least two of R⁶, R⁷, and R⁸ are the same.

At step 206, in some embodiments, the method comprises contacting the first reactant and the second reactant to form a reaction product. In some embodiments, the contacting comprises bringing the first reactant and the second reactant into immediate or close proximity. In some embodiments, the contacting comprises bringing the first reactant and the second reactant into direct physical contact. In some embodiments, the contacting comprises mixing or stirring the first reactant and the second reactant compound. In some embodiments, the contacting comprises agitating the first reactant and the second reactant. In some embodiments, the contacting comprises adding or combining the first reactant and the second reactant to a reaction vessel. In some embodiments, the contacting comprises adding at least one of the first reactant, the second reactant, or any combination thereof, to at least one solution, a solvent, or a reaction medium. In some embodiments, the contacting comprises adding the first reactant to a first solution and combining the first solution and the second reactant in a reaction vessel. In some embodiments, the contacting comprises adding the second reactant to a second solution and combining the first reactant and the second solution in a reaction vessel.

In some embodiments, the contacting is performed in a presence of a solvent. In some embodiments, the solvent comprises an alkane. In some embodiments, the solvent comprises a hexane. In some embodiments, the solvent comprises an ether. In some embodiments, the solvent comprises a diethyl ether. In some embodiments, the solvent comprises a tetrahydrofuran. In some embodiments, the solvent comprises a toluene. In some embodiments, the solvent comprises a benzene. In some embodiments, the solvent comprises a xylene. In some embodiments, the solvent comprises an alcohol. In some embodiments, the method is performed without any solvent or with minimal solvent.

In some embodiments, the contacting comprises contacting the first reactant and the second reactant at a temperature of −80° C. to 25° C., or any range or subrange between −80° C. to 25° C. In some embodiments, the contacting comprises contacting the first reactant and the second reactant at a temperature of −75° C. to 25° C., −70° C. to 25° C., −65° C. to 25° C., −60° C. to 25° C., −55° C. to 25° C., −50° C. to 25° C., −45° C. to 25° C., −40° C. to 25° C., −35° C. to 25° C., −30° C. to 25° C., −25° C. to 25° C., −20° C. to 25° C., −15° C. to 25° C., −10° C. to 25° C., −5° C. to 25° C., 0° C. to 25° C., 5° C. to 25° C., 10° C. to 25° C., 15° C. to 25° C., 20° C. to 25° C., −80° C. to 20° C., −80° C. to 15° C., −80° C. to 10° C., −80° C. to 5° C., −80° C. to 0° C., −80° C. to −5° C., −80° C. to −10° C., −80° C. to −15° C., −80° C. to −20° C., −80° C. to −25° C., −80° C. to −30° C., −80° C. to −35° C., −80° C. to −40° C., −80° C. to −45° C., −80° C. to −50° C., −80° C. to −55° C., −80° C. to −60° C., −80° C. to −65° C., −80° C. to −70° C., or −80° C. to −75° C.

In some embodiments, the reaction product comprises the formula:

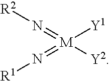

In some embodiments, the reaction product comprises the formula:

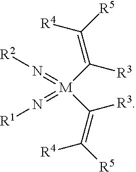

In some embodiments, the reaction product has a purity of at least 90% as determined TGA residue at 400° C. For example, in some embodiments, the reaction product has a purity of, at least 91%, at least 92%, at least 93%, at least 94%, at least 95%, at least 96%, at least 97%, at least 98%, at least 99%, at least 99.5%, at least 99.9%, at least 99.95%, or at least 99.99% as determined by a TGA residue at 400° C.

In some embodiments, the reaction product has a purity of 90% to 99.99%, or any range or subrange between 90% to 99.99%, as determined by a TGA residue at 400° C. In some embodiments, the reaction product has a purity of 90% to 99.95%, 90% to 99.9%, 90% to 99.5%, 90% to 99%, 90% to 98%, 90% to 97%, 90% to 96%, 90% to 95%, 90% to 94%, 90% to 93%, 90% to 92%, 90% to 91%, 91% to 99.99%, 92% to 99.99%, 93% to 99.99%, 94% to 99.99%, 95% to 99.99%, 96% to 99.99%, 97% to 99.99%, 98% to 99.99%, 99% to 99.99%, 99.5% to 99.99%, 99.9% to 99.99% or 99.95 to 99.99%, as determined by a TGA residue at 400° C.

In some embodiments, the reaction product comprises less than 10% by weight of a halide based on a total weight of the reaction product. In some embodiments, the reaction product comprises less than 9%, less than 8%, less than 7%, less than 6%, less than 5%, less than 4%, less than 3%, less than 2%, less than 1%, less than 0.5%, less than 0.1%, less than 0.05%, or less than 0.01% by weigh of a halide based on a total weight of the reaction product.

In some embodiments, the reaction product comprises 0.01% to 10%, or any range or subrange between 0.01% to 10%, by weight of a halide based on a total weight of the reaction product. In some embodiments, the reaction product comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.1%, 0.01% to 0.05%, 0.05% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10% by weight of a halide based on a total weight of the reaction product.

Any one or more of the embodiments disclosed herein shall be understood to be combinable without departing from the scope or spirit of the disclosure.

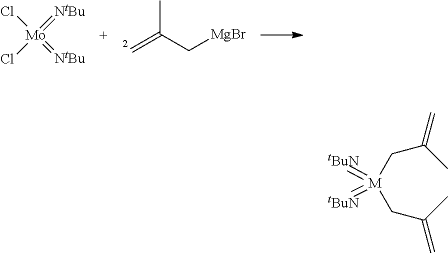

### Example 1: Synthesis of bis(tert-butylimido)bis(methallyl) molybdenum (VI) from (^{t}BuN=)₂MoCl₂ and methallylmagnesium bromide

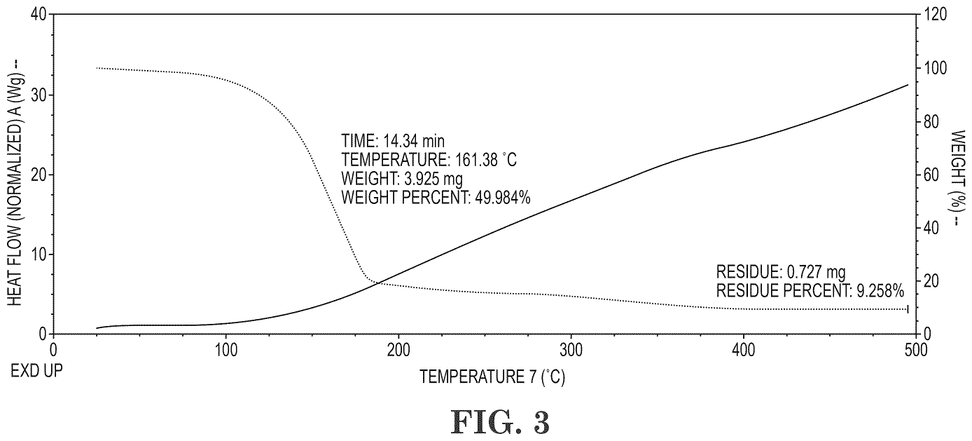

A (^{t}BuN=)₂MoCl₂ was contacted with a methallylmagnesium bromide in a solution. The solution was kept at a temperature of −80° C. to 25° C. The crude product was recovered by stripping the solvent in the solution by vacuum. The crude product was determined to comprise bis(tert-butylimido)bis(methallyl) molybdenum (VI). The crude product was analyzed using thermogravimetric analysis (TGA). The TGA, as shown in FIG. 3, showed less than 10% overall residuals at 400° C.

### ASPECTS

Various Aspects are described below. It is to be understood that any one or more of the features recited in the following Aspect(s) can be combined with any one or more other Aspect(s).

Aspect 1. A composition comprising:
a precursor compound of the formula:

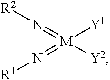

where:
   M comprises at least one of molybdenum, tungsten, chromium, or any combination thereof;
   R¹ and R² independently comprise at least one of an alkyl, an alkenyl, an alkynyl, or any combination thereof, and
   Y¹ and Y² independently comprises at least one of a hydrocarbon functional group that does not contain a β-hydrogen, a silyl, an alkoxy, an amine, a thiol, or any combination thereof, or
   Y¹ and Y² are bonded to form a cyclic ring;
wherein the precursor compound is present in an amount of at least 90% by weight based on a total weight of the composition.

Aspect 2. The composition according to Aspect 1, wherein Y¹ and Y² independently comprise at least one of:

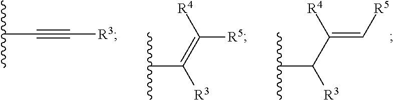

or
any combination thereof,
   wherein R³, R⁴, and R⁵ independently comprise at least one of an alkyl, an alkenyl, an alkynyl, or any combination thereof.

Aspect 3. The composition according to any one of Aspects 1-2, wherein, when Y¹ and Y² are bonded to form a cyclic ring, the cyclic ring has the formula:

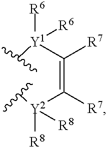

where:
   Y¹ and Y² independently comprises at least one of an oxygen, a nitrogen, a sulfur, or any combination thereof, and
   each R⁶, R⁷, and R⁸ independently comprise at least one of an alkyl, an alkenyl, an alkynyl, or any combination thereof.
      Aspect 4. The composition according to any one of Aspects 1-3, wherein the precursor compound is present in an amount of 90% to 99.99% by weight based on the total weight of the composition.
      Aspect 5. The composition according to any one of Aspects 1-4, wherein the precursor compound comprises the formula:

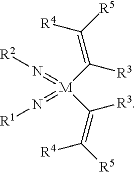

Aspect 6. A method comprising:
obtaining a precursor compound of the formula:

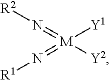

where:
   M comprises at least one of molybdenum, tungsten, chromium, or any combination thereof,
   R¹ and R² independently comprise at least one of an alkyl, an alkenyl, an alkynyl, or any combination thereof, and
   Y³ and Y² independently comprise a hydrocarbon functional group that does not contain at least one of a β-hydrogen, a silyl, an alkoxy, an amine, a thiol, or any combination thereof, or
   Y¹ and Y² are bonded to form a cyclic ring;
heating the precursor compound to obtain a vaporized precursor; and contacting a substrate with the vaporized precursor to obtain a film on the substrate.
   Aspect 7. The method according to Aspect 6, wherein Y¹ and Y² independently comprise at least one of:

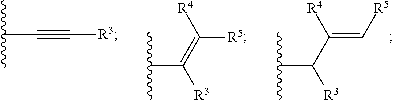

any combination thereof,
   wherein R³, R⁴, and R⁵ independently comprise at least one of alkyl, an alkenyl, an alkynyl, or any combination thereof.
      Aspect 8. The method according to any one of Aspects 6-7, wherein, when Y¹ and Y² are bonded to form a cyclic ring, the cyclic ring has the formula:

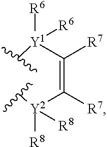

where:
   Y¹ and Y² independently comprises at least one of an oxygen, a nitrogen, a sulfur, or any combination thereof, and
   each R⁶, R⁷, and R⁸ independently comprise at least one of alkyl, an alkenyl, an alkynyl, or any combination thereof.
      Aspect 9. The method according to any one of Aspects 6-8, wherein the precursor compound comprises the formula:

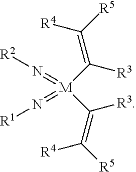

Aspect 10. The method according to any one of Aspects 6-9, wherein the film comprises less than 0.1% by weight of a halide based on a total weight of the film.
Aspect 11. The method according to any one of Aspects 6-10, wherein the film does not comprise a halide.
Aspect 12. The method according to any one of Aspects 6-11, wherein the film comprises at least one of a molybdenum nitride, a chromium nitride, a tungsten nitride, or any combination thereof.
Aspect 13. A method comprising:
obtaining a first reactant of the formula:

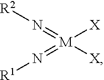

where:
   M comprises at least one of molybdenum, tungsten, chromium, or any combination thereof,
   R¹ and R² independently comprise at least one of an alkyl, an alkenyl, an alkynyl, or any combination thereof,
   each X independently comprises a halide;
obtaining a second reactant of the formula:

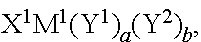

where:
   X¹ comprises a halide;
   M¹ comprises at least one of an alkali metal, an alkaline earth metal, or any combination thereof,
   a is 0 or 1;
   b is 0 or 1; and
   Y¹ and Y² independently comprise a hydrocarbon functional group that does not contain at least one of a β-hydrogen, a silyl, an alkoxy, an amine, a thiol, or any combination thereof, or
   Y¹ and Y² are bonded to form a cyclic ring; and
contacting the first reactant and the second reactant to form a reaction product,
   wherein the reaction product comprises the formula:

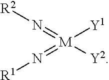

Aspect 14. The method according to Aspect 13, wherein Y¹ and Y² independently comprise at least one of:

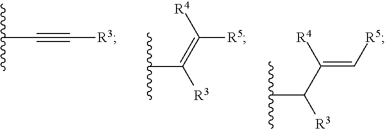

or
any combination thereof,
   wherein R³, R⁴, and R⁵ independently comprise at least one of alkyl, an alkenyl, an alkynyl, or any combination thereof.
      Aspect 15. The method according to any one of Aspects 13-14, wherein, when Y¹ and Y² are bonded to form a cyclic ring, the cyclic ring is of the formula:

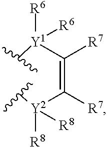

where:
   Y¹ and Y² independently comprises at least one of an oxygen, a nitrogen, a sulfur, or any combination thereof, and
   each R⁶, R⁷, and R⁸ independently comprise at least one of alkyl, an alkenyl, an alkynyl, or any combination thereof.
      Aspect 16. The method according to any one of Aspects 13-15, wherein the reaction product has a purity of at least 90% as determined by a TGA residue at 400° C.
      Aspect 17. The method according to any one of Aspects 13-16, wherein the reaction product has a purity of 90% to 99.99% as determined by a TGA residue at 400° C.
      Aspect 18. The method according to any one of Aspects 13-17, wherein the reaction product comprises less than 10% by weight of a halide based on a total weight of the reaction product.
      Aspect 19. The method according to any one of Aspects 13-18, wherein the contacting comprises contacting the first reactant and the second reactant at a temperature of −80° C. to 25° C.
      Aspect 20. The method according to any one of Aspects 13-19, wherein the reaction product comprises the formula:

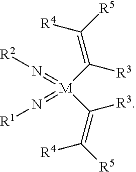

What is claimed is:

1. A composition comprising:
a precursor compound of the formula: 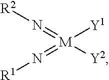
where:
M comprises at least one of molybdenum, tungsten, chromium, or any combination thereof,
R¹ and R² independently comprise at least one of an alkyl, an alkenyl, an alkynyl, or any combination thereof, and
Y¹ and Y² independently comprise at least one of a hydrocarbon functional group that does not contain a β-hydrogen, a silyl, an alkoxy, an amine, a thiol, or any combination thereof, or
Y¹ and Y² are bonded to form a cyclic ring;
wherein the precursor compound is present in an amount of at least 90% by weight based on a total weight of the composition.

2. The composition of claim 1, wherein Y¹ and Y² independently comprise at least one of: 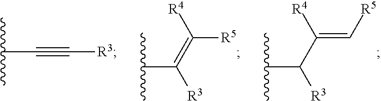
or
any combination thereof,
wherein R³, R⁴, and R⁵ independently comprise at least one of an alkyl, an alkenyl, an alkynyl, or any combination thereof.

3. The composition of claim 1, wherein, when Y¹ and Y² are bonded to form a cyclic ring, the cyclic ring has the formula: 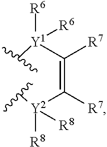
where:
Y¹ and Y² independently comprise at least one of an oxygen, a nitrogen, a sulfur, or any combination thereof, and
each R⁶, R⁷, and R⁸ independently comprise at least one of an alkyl, an alkenyl, an alkynyl, or any combination thereof.

4. The composition of claim 1, wherein the precursor compound is present in an amount of 90% to 99.99% by weight based on the total weight of the composition.

5. The composition of claim 1, wherein the precursor compound comprises the formula:

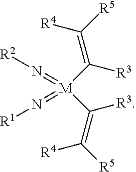

6. A method comprising:
obtaining a precursor compound of the formula: 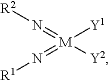
where:
M comprises at least one of molybdenum, tungsten, chromium, or any combination thereof,
R¹ and R² independently comprise at least one of an alkyl, an alkenyl, an alkynyl, or any combination thereof, and
Y¹ and Y² independently comprise a hydrocarbon functional group that does not contain at least one of a β-hydrogen, a silyl, an alkoxy, an amine, a thiol, or any combination thereof, or
Y¹ and Y² are bonded to form a cyclic ring;
heating the precursor compound to obtain a vaporized precursor; and
contacting a substrate with the vaporized precursor to obtain a film on the substrate.

7. The method of claim 6, wherein Y¹ and Y² independently comprise at least one of: 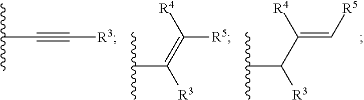
or
any combination thereof,
wherein R³, R⁴, and R⁵ independently comprise at least one of alkyl, an alkenyl, an alkynyl, or any combination thereof.

8. The method of claim 6, wherein, when Y¹ and Y² are bonded to form a cyclic ring, the cyclic ring has the formula: 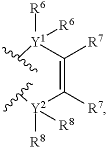
where:
Y¹ and Y² independently comprise at least one of an oxygen, a nitrogen, a sulfur, or any combination thereof, and
each R⁶, R⁷, and R⁸ independently comprise at least one of alkyl, an alkenyl, an alkynyl, or any combination thereof.

9. The method of claim 6, wherein the precursor compound comprises the formula:

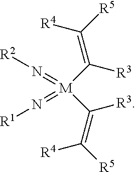

10. The method of claim 6, wherein the film comprises less than 0.1% by weight of a halide based on a total weight of the film.

11. The method of claim 6, wherein the film does not comprise a halide.

12. The method of claim 6, wherein the film comprises at least one of a molybdenum nitride, a chromium nitride, a tungsten nitride, or any combination thereof.

13. A method comprising:
obtaining a first reactant of the formula: 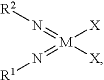
where:
M comprises at least one of molybdenum, tungsten, chromium, or any combination thereof,
R¹ and R² independently comprise at least one of an alkyl, an alkenyl, an alkynyl, or any combination thereof,
each X independently comprises a halide;
obtaining a second reactant of the formula: 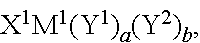
where:
X¹ comprises a halide;
M¹ comprises at least one of an alkali metal, an alkaline earth metal, or any combination thereof,
a is 0 or 1;
b is 0 or 1; and
Y¹ and Y² independently comprise a hydrocarbon functional group that does not contain at least one of a β-hydrogen, a silyl, an alkoxy, an amine, a thiol, or any combination thereof, or
Y¹ and Y² are bonded to form a cyclic ring; and
contacting the first reactant and the second reactant to form a reaction product,
wherein the reaction product comprises the formula:

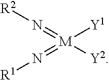

14. The method of claim 13, wherein Y¹ and Y² independently comprise at least one of: 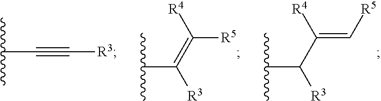
or
any combination thereof,
wherein R³, R⁴, and R⁵ independently comprise at least one of alkyl, an alkenyl, an alkynyl, or any combination thereof.

15. The method of claim 13, wherein, when Y¹ and Y² are bonded to form a cyclic ring, the cyclic ring is of the formula: 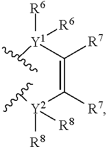
where:
Y¹ and Y² independently comprises at least one of an oxygen, a nitrogen, a sulfur, or any combination thereof, and
each R⁶, R⁷, and R⁸ independently comprise at least one of alkyl, an alkenyl, an alkynyl, or any combination thereof.

16. The method of claim 13, wherein the reaction product has a purity of at least 90% as determined by a TGA residue at 400° C.

17. The method of claim 13, wherein the reaction product has a purity of 90% to 99.99% as determined by a TGA residue at 400° C.

18. The method of claim 13, wherein the reaction product comprises less than 10% by weight of a halide based on a total weight of the reaction product.

19. The method of claim 13, wherein the contacting comprises contacting the first reactant and the second reactant at a temperature of −80° C. to 25° C.

20. The method of claim 13, wherein the reaction product comprises the formula: [chemical structure]
